(19) United States
(12) Patent Application Publication
(10) Pub. No.: US 2005/0035795 A1
(43) Pub. Date: Feb. 17, 2005

(54) Circuit for optimizing zener diode bias current

(76) Inventor: Chi Fai Liu, Yuen Long (HK)

Correspondence Address: Donald L. Bartels;Coudert Brothers LLP, Two Palo Alto Square, 3000 El Camino Real 4th Floor, Palo Alto, CA, 94306-2121, US

(21) Appl. No.: 10/616,201

(22) Filed: Jul. 8, 2003

(51) Int. Cl. H03K 3/00

(52) U.S. Cl. 327/131

(57) ABSTRACT

A circuit is provided that efficiently provides the required biasing current for a zener diode that provides a reference voltage to clamp the peak voltage of the sawtooth waveform generated by a sawtooth generator circuit. In a preferred embodiment, the present invention provides a circuit that switches the zener biasing current off, except during the short period when the referencing voltage is needed to provide the clamping function, thereby significantly reducing the current required.

### FIELD OF INVENTION

The present invention relates to sawtooth waveform generator circuits, and more particularly, to a circuit for a sawtooth generator that efficiently controls the bias current for a zener diode which provides a reference voltage for limiting the peak voltage of the sawtooth waveform.

### BACKGROUND OF THE INVENTION

Many electronic circuits require that a fixed reference voltage level be provided therein. One way to provide this reference voltage is through use of a zener diode. A zener diode conducts like a normal diode in the forward direction, but in the reverse direction will not allow the voltage across the diode to exceed the rated zener voltage. A rated zener voltage of below four volts is typical for low power zener diodes. The rated zener voltage provides the reference voltage level. In order for the zener diode to provide the rated zener voltage with good regulation, it must be provided with a constant bias current. One drawback of the zener diode, particularly low voltage zener diodes, is that a constant bias current on the order of one milliamp is required to produce the rated zener voltage. This level of bias current is undesirable especially for low power applications.

One known application that utilizes a zener diode to provide a reference voltage is a sawtooth waveform generator circuit. Many applications, such as a pulse width modulator, require that a sawtooth voltage signal be provided. The sawtooth generator circuit typically produces a sawtooth waveform that varies periodically between a lower voltage limit and an upper voltage limit. The sawtooth characteristic of the waveform is typically produced by quickly charging and slowly discharging a capacitor. It is often desirable to limit the peak voltage of the sawtooth when the capacitor is charged with a very short current pulse. For limiting the peak voltage, a fixed voltage reference is typically used as part of a clamp circuit to clamp the peak to a voltage that is a predetermined function of the reference voltage level.

FIG. 1 shows a schematic diagram of a prior art circuit 10 that includes a sawtooth generator circuit 60 and a zero crossing detector 30. The sawtooth generator circuit 60 includes a zener diode to provide a reference voltage for limiting the peak of the generated sawtooth waveform. The circuit 10 of FIG. 1 receives an input AC voltage at terminals 6, 8 and generates a sawtooth waveform voltage signal at node 35. The zero crossing detector 30 is connected to the AC input terminals 6, 8 and has an output at a terminal 2. The sawtooth generator circuit 60 includes a transistor 22 having a base coupled through a resistor 20 to the terminal 2, a collector, and an emitter. A resistor 18, a resistor 16, and a resistor 44 are connected in series between V_{cc} and the collector of transistor 22. V_{cc} is typically 5.5V for the sawtooth generator circuit 60. The emitter of transistor 22 is coupled to a reference potential, preferably ground. A capacitor 24 is connected across the emitter and collector of transistor 22. A capacitor 40 is connected between the junction of resistors 16, 44 at a node 29 and ground.

Sawtooth generator circuit 60 includes a transistor 32 which has a base coupled to the junction of resistor 16 and resistor 18 at node 45, a collector, and an emitter connected to the node 29. A resistor 38 is connected in series with a capacitor 28, at node 35, between the collector of transistor 32 and ground. A constant current source 48 is connected in parallel with capacitor 28.

As shown in FIG. 1, sawtooth generator 60 includes a diode 34 connected in series between node 35 and the junction of a resistor 36 and a zener diode 26. Resistor 36 and the zener diode 26 are connected in series, at a node 33, between node 29 and ground. The diode 34 has a cathode connected to node 33 and an anode connected to node 35. Zener diode 26 has a cathode connected to node 33 and an anode connected to ground.

In operation, the zero crossing detector 30 generates a short pulse at terminal 2 every time the AC input voltage crosses zero. The pulsed voltage signal at terminal 2 is coupled to the base of transistor 22, such that transistor 22 is switched into a conduction state only at the zero crossings of the AC input. The conduction state of transistor 22 causes transistor 32 to conduct and quickly charging capacitor 28 at the beginning of the zero crossing detector voltage pulse, thereby generating the rising edge of the sawtooth output at node 35. Once each zero crossing interval of the AC input ends, the zero crossing detector 30 stops generates the pulse at terminal 2 causing transistor 22 to switch to a non-conduction state. Capacitor 28 will then be slowly discharged through constant current source 48. The constant current source 48 conducts a fixed current from capacitor 28 to discharge capacitor 28 linearly, thereby forming a downward ramp of the sawtooth wave at node 35.

The quick charging and discharging circuit requires that a fixed voltage reference be provided in order to limit the maximum voltage when the capacitor 28 is charged with a very short current pulse. Circuit 10 provides a constant biasing current required by zener diode 26 to produce its rated zener voltage, typically around four volts for a low power zener diode. Zener diode 26 functions to cause the peak of the sawtooth waveform at node 35 to be limited (i.e., “clamped”) to the rated zener voltage.

In the sawtooth generator circuit 60, the zener diode, can typically requires a constant bias current on the order of about one milliamp. This is true even for low power variant zener diodes. Many low power applications require that the total current allowed in a device be limited to significantly below one milliamp. Thus, the constant bias current requirement of sawtooth generator 60 in FIG. 1 is undesirable especially for low power applications.

A need therefore exists for significantly reducing the amount of bias current that is required for the zener diode for the sawtooth generator circuit, while maintaining the benefits provided by the use of a zener diode, namely a fixed reference voltage for limiting the maximum sawtooth waveform voltage when the capacitor is charged using a very short current pulse.

### SUMMARY OF THE INVENTION

The present invention solves the problems of prior art devices by providing a sawtooth waveform generator circuit having a zener diode controlled such that the bias current for the zener diode is present only during the time that a capacitor across which the sawtooth waveform is generated is being changed, thereby significantly reducing the power consumption caused by the zener diode's bias current. In a preferred embodiment, the present invention provides a circuit that prevents the supplying of bias current to the zener diode except during the very short period pulses when the referencing voltage provided by the zener diode is needed to limit the sawtooth waveform voltage. Consequently, the circuit of the present invention has the advantage of overcoming the drawbacks of known circuits by reducing the power loss associated with the zener diode bias current and by doing so using standard circuit components at minimal cost, without adversely affecting the reliability of the overall system. The circuit of the present invention is applicable to a wide variety of applications that utilize a sawtooth waveform generator.

Broadly stated, the present invention provides a sawtooth generator for generating a sawtooth waveform as a function of a periodic pulse coupled to the generator, comprising a first capacitor that is charged as a function of the periodic pulse and then discharged at a predetermined rate such that the voltage on the first capacitor defines the sawtooth waveform; and a reference circuit for limiting the peak voltage of the sawtooth waveform as a function of a predetermined reference voltage, the reference circuit including a zener diode for generating the predetermined reference voltage in response to a predetermined bias current when the zener diode is reverse biased, a first circuit coupled between the zener diode and the first capacitor and operative to limit the peak voltage on the capacitor as a function of the predetermined reference voltage, and a second circuit for providing the predetermined bias current as a function of the periodic pulse such that the predetermined bias current is turned on during the time the first capacitor is being charged and off for a substantial amount of the time when the first capacitor is discharging.

### BRIEF DESCRIPTION OF THE DRAWINGS

The forgoing aspects and the attendant advantages of the present invention will become more readily appreciated by reference to the following detailed description, when taken in conjunction with the accompanying drawings, wherein:

FIG. 1 shows a schematic diagram of a prior art circuit 10 including a sawtooth generator circuit and a zero crossing detector wherein a zener diode is used to limit the peak voltage of a generated sawtooth waveform;

FIG. 2 is a schematic diagram of an embodiment of a circuit having a sawtooth generator circuit and a zero crossing detector and including the bias current control of a zener diode according to the present invention.

FIG. 3 shows an exemplary sawtooth waveform output for a circuit according to an embodiment of the present invention;

FIG. 4 illustrates calculated current waveforms for the magnitude of the zener bias current for the circuits shown in FIGS. 1 and 2; and

FIG. 5 illustrates calculated current waveforms for exemplary circuits as shown in FIGS. 1 and 2.

### DETAILED DESCRIPTION OF THE INVENTION

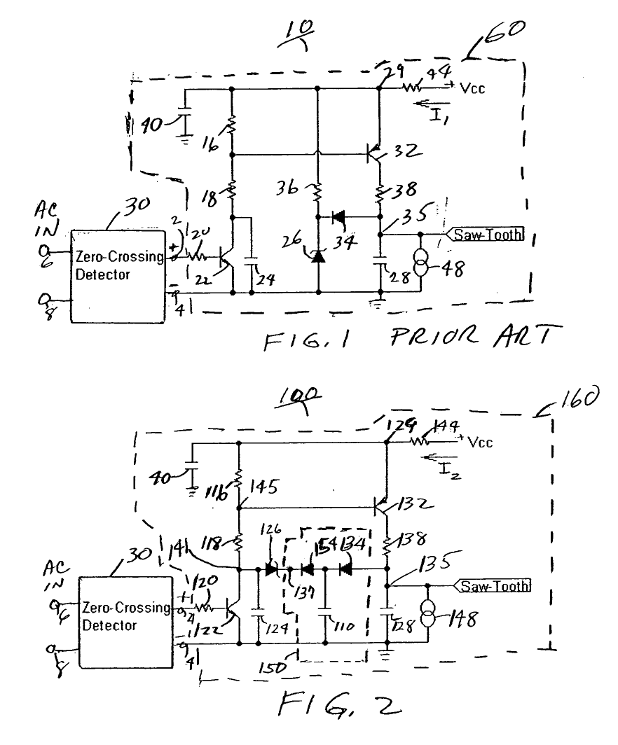

The present invention comprises a circuit for a sawtooth generator that efficiently controls the bias current for a zener diode which provides a reference voltage for clamping the peak voltage of the sawtooth waveform. In a preferred embodiment, the present invention provides a circuit that switches the zener diode biasing current off except during the very short period when the reference voltage provided by the zener diode is required to provide this clamping function. Thus, the present invention overcomes the drawbacks of the known circuits by significantly reducing the zener bias current required for the circuit. The present invention is further described with reference to FIGS. 2-5.

FIG. 2 is a schematic diagram of an embodiment of a circuit 100 having a sawtooth generator circuit 160 and a zero crossing detector 30 and including the bias current control of a zener diode according to the present invention. The circuit 100 of FIG. 2 receives an input AC voltage at terminals 6, 8 and generates a sawtooth waveform voltage signal at a node 135. A zero crossing detector 30 is connected to the AC input terminals 6, 8 and generates a short pulse at terminal 2 every time the AC input voltage crosses zero. Although a zero crossing detector is shown in FIG. 2, any suitable pulse generator that generates a short pulse may be used in place of the zero crossing detector in order to practice the invention. The sawtooth generator circuit 160 includes a transistor 122 having a base coupled through a resistor 120 to the terminal 2, a collector and an emitter. A resistor 118, a resistor 116, and a resistor 144 are connected in series between V_{cc}, preferably at 5.5V, and the collector of transistor 122. The collector of transistor 122 is coupled to the resistor 118 at a node 141. The emitter of transistor 122 is coupled to a reference potential, preferably ground. A capacitor 124 is connected across the emitter and collector of transistor 122. Capacitor 124 is preferably provided for improving the evenness of the zero-crossing time duration over a range of different input AC voltages input to the zero-crossing detector 30. A capacitor 140 is a decoupling capacitor connected between the junction of resistors 116, 144 at a node 129 and ground.

Sawtooth generator circuit 160 includes a transistor 132 which has a base coupled to the junction of resistor 116 and resistor 118 at node 145, a collector, and an emitter connected to the node 129. A capacitor 128 is coupled through a resistor 138 to the collector of transistor 132. The resistor 138 is connected in series with the capacitor 128, at node 135, between the collector of transistor 132 and ground. A constant current source 148 is connected in parallel with capacitor 128. For sawtooth generator circuit 160, the sawtooth voltage signal is generated across capacitor 128 between node 135 and ground.

Circuit 100 includes a reference circuit comprising a zener diode 126 and a reference coupling circuit 150 connected between node 141 and node 135. Reference coupling circuit 150 includes a diode 154 and a diode 134 connected in series with zener diode 126 between node 141 and node 135. Zener diode 126 has an anode connected to node 141 and a cathode connected to a cathode of the diode 154 at a node 137. The zener diode 126 preferably has a rated zener voltage of 3V. Diode 154 has an anode connected to a cathode of diode 134. The anode of the diode 134 is connected to node 135. Reference coupling circuit 150 also includes a capacitor 110 connected between the junction of the diodes 154, 134 and ground.

In operation, the zero crossing detector 30 in FIG. 2 detects each zero crossing of the AC input voltage and generates a short pulse at terminal 2 every time the AC input voltage crosses zero. The sawtooth generator circuit 160 generates a sawtooth waveform based on the pulses generated by the zero crossing detector 30. The pulsed voltage signal at terminal 2 is coupled to the base of transistor 122, such that transistor 122 is switched into a conduction state only at the zero crossings of the AC input. The conduction state of transistor 122 causes transistor 132 to conduct and quickly begin charging capacitor 128. Immediately after each zero crossing detection pulse ends, transistor 122 stop conducting. Capacitor 128 will then be slowly discharged through the constant current source 148. The constant current source 148 conducts a fixed current from capacitor 128 to discharge capacitor 128 linearly, thereby forming a downward ramp of the sawtooth wave at node 135.

A fixed voltage reference is required to clamp the maximum voltage at which the capacitor 128 is charged. As described above, in the prior art sawtooth generator circuit shown in FIG. 1, a constant biasing current is provided to the zener diode 26 to produce its rated zener voltage. The peak of the sawtooth voltage output is limited as a function of this rated zener voltage. The zener diode can typically require a constant bias current on the order of about one milliamp. This is true even for low power variant zener diodes. Many low power applications demand that the total current allowed in a device be limited to significantly below the level of the required bias current. The present invention has the advantage of significantly reducing the bias current required for the sawtooth generator circuit, as will be described in further detail.

The zener diode 126 is arranged so that, when provided with the required bias current, it causes the peak of the sawtooth voltage signal at node 135 to be limited as a function of the rated zener voltage. In sawtooth generator 160, zener diode 126 is switched on and off by transistor 122. Thus, a bias current is provided to switch on the zener diode 126 only during the time that pulses are generated by zero crossing detector 30.

During a very short period immediately after the zero crossing, the voltage on the collector pin of transistor 122 will rise from zero potential back to Vcc. However, transistor 132 will not completely shut off unless this voltage goes very near Vcc. This weak, instantaneous conduction of transistor 132 is sufficient to charge capacitor 128 to a voltage approaching Vcc, now that zener 126 has no drain path. In order to avoid having the peak of the sawtooth voltage signal at node 135 being unclamped and uncontrolled during this short period of time, capacitor 110 is preferably included in the reference coupling circuit 150. Capacitor 110 has a substantially larger capacitance than that for capacitor 128, such that capacitor 110 maintains a fairly stable voltage defined by the zener diode 126 and forward drop of diode 154. Capacitor C110 functions to absorb the stray current from transistor 132 during the short period of time after the zero crossing, draining it to ground through its sufficiently larger capacitance, without any significant increase in the voltage across capacitor 110 and capacitor 128. Diode 154 functions to prevent capacitor 110 from being charged higher than the voltage being clamped when transistor 122 is turned off after the zero crossing detector pulse ends. Diode 134 functions to block capacitor 110 from discharging. Thus, capacitor 110 remains constant at a voltage defined by the zener diode 126 plus the forward drop on diode 154.

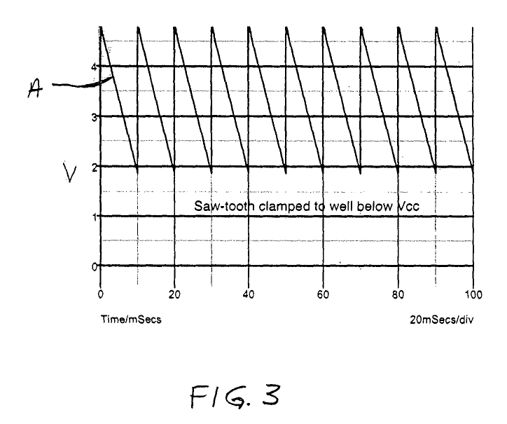

FIG. 3 shows the sawtooth waveform output for a circuit according to an embodiment of the present invention. Trace A is the voltage waveform of the sawtooth output voltage at node 135 for the embodiment of FIG. 2. The peak of the sawtooth waveform is clamped to the rated zener voltage plus the voltage drop across the two diode in series with the zener diode. As can be seen, the peak of the sawtooth voltage output is limited to a voltage below V_{cc}. V_{cc} is preferably at 5.5 V for the circuit.

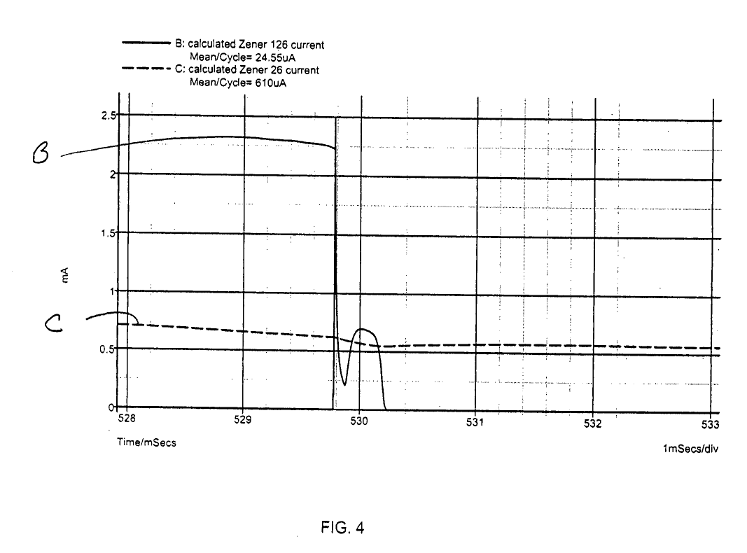

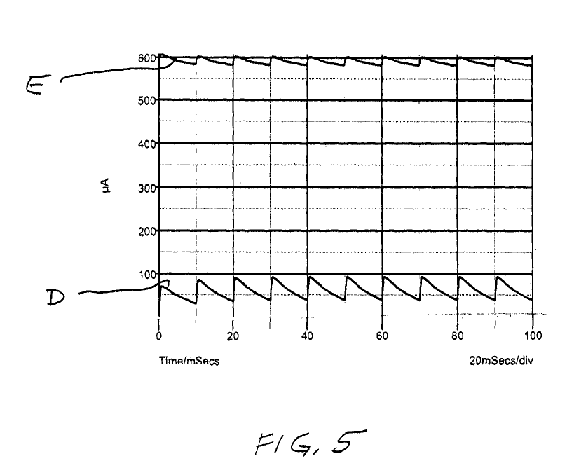

FIG. 4 illustrates current waveforms for the zener bias currents generated by the circuits shown in FIGS. 1 and 2. Trace C is the zener current for zener diode 26 in the prior art circuit shown in FIG. 1. Trace B is the zener current for zener diode 126 in the circuit shown in FIG. 2. For exemplary circuits, the mean current for the zener diode 126 for the prior art circuit in FIG. 1, as represented by Trace C, was calculated at 568.6 μA. By comparison, the mean current for the zener diode 126 for the embodiment of the present invention in FIG. 2, as represented by Trace B, was measured at 36.81 μA. As seen in FIG. 4, for the embodiment shown in FIG. 2, the zener diode biasing current is switched off, except during the very short period pulses when the referencing voltage provided by the zener diode is needed. In the above example, the present invention thus provides a 93.5% reduction in mean bias current.

FIG. 5 illustrates current waveforms for the exemplary circuits shown in FIGS. 1 and 2. Trace E is the calculated total current I₁, through resistor 44, for the prior art circuit shown in FIG. 1. Trace F is the calculated total current I₂, through resistor 144, for the circuit in FIG. 2. For the waveforms shown, calculations were made for exemplary circuits with the calculated current being 590.9 μA RMS for I₁, and 62.74 μA RMS for I2. Thus, for these exemplary circuits, a power saving calculated at approx. 89.4% is achieved by the present invention.

Consequently, the present invention has the advantage of overcoming the drawbacks of known circuits by reducing the zener diode bias current and by doing so using standard circuit components.

The foregoing detailed description of the invention has been provided for the purposes of illustration and description. Although exemplary embodiments of the present invention have been described in detail herein with reference to the accompanying drawings, it is to be understood that the invention is not limited to the precise embodiments disclosed, and that various changes and modifications to the present invention are possible in light of the above teaching.

1. A sawtooth generator for generating a sawtooth waveform as a function of a periodic pulse coupled to said generator, comprising:
a first capacitor that is charged as a function of said periodic pulse and then discharged at a predetermined rate such that the voltage on said first capacitor defines said sawtooth waveform; and
a reference circuit for limiting the peak voltage of said sawtooth waveform as a function of a predetermined reference voltage, said reference circuit including a zener diode for generating said predetermined reference voltage in response to a predetermined bias current when said zener diode is reverse biased, a first circuit coupled between said zener diode and said first capacitor and operative to limit the peak voltage on said capacitor as a function of said predetermined voltage, and a second circuit for providing said predetermined bias current as a function of said periodic pulse such that said predetermined bias current is turned on during the time said first capacitor is being charged and off for a substantial amount of the time when said first capacitor is discharging.

2. The sawtooth generator of claim 1, wherein said periodic pulse is generated by a zero crossing detector having two terminals to which an AC input is coupled, said detector for detecting each zero crossing of said AC input and generating said periodic pulse for each said zero crossing.

3. The sawtooth generator of claim 1, wherein said second circuit comprises:
a first transistor having a base, an emitter coupled to ground, and a collector; said zener diode having an anode and a cathode; said collector coupled to said anode of said zener diode at a first node; said periodic pulse being coupled to said base through a first resistor such that said first transistor is switched on as a function of said periodic pulse, and
a second, third, and fourth resistor connected in series between a DC supply voltage (V_{cc}), and said first node;
wherein said predetermined bias current is provided to said zener diode as a function of said periodic pulse.

4. The sawtooth generator of claim 3, wherein said first circuit comprises a first and second diode connected in series with said zener diode between the first node and said first capacitor at a second node, and a second capacitor connected between the junction of said first and second diodes and ground and being charged by said zener diode to said predetermined reference voltage, said second capacitor having a capacitance substantially greater than the capacitance of said first capacitor such that said second capacitor maintains said predetermined reference voltage for a predetermined period of time after the end of each said periodic pulse for limiting the peak voltage of said sawtooth waveform.

5. The sawtooth generator of claim 4, wherein said cathode of said zener diode is connected to a cathode of said first diode at a third node, said first diode having an anode connected to a cathode of said second diode and said second diode having an anode connected to said first capacitor at said second node.

6. The sawtooth generator of claim 3, wherein said second circuit further comprises:
a third capacitor connected in parallel across said emitter and collector of said first transistor.

7. The sawtooth generator of claim 1, further including a second transistor having a base coupled to the junction of said second and third resistor, an emitter connected to the junction of said third and fourth resistor, and a collector coupled to said first capacitor through a fifth resistor.

8. The sawtooth generator of claim 1, further including a constant current source for discharging said first capacitor.

9. In a sawtooth generator for generating a sawtooth waveform at an output terminal and including a first capacitor, a first circuit for charging said first capacitor to a predetermined voltage as a function of an input pulse, a second circuit for discharging said first capacitor at a controlled rate, and a third circuit for generating a voltage at said output terminal as a function of the voltage across said first capacitor, a reference circuit for limiting the peak voltage on said first capacitor comprising:
a zener diode for generating a predetermined reference voltage in response to a predetermined bias current when said zener diode is reverse biased,
a fourth circuit coupled between said zener diode and said first capacitor and operative to limit the peak voltage on said capacitor as a function of said predetermined reference voltage; and
a fifth circuit for providing said predetermined bias current as a function of said periodic pulse such that said predetermined bias current is turned on during the time said first capacitor is being charged and off for a substantial amount of the time when said first capacitor is discharging.

10. A reference circuit for providing a reference voltage during a predetermined time interval comprising:
a zener diode for providing said reference voltage in response to a predetermined bias current when said zener diode is reverse biased, and
a bias control circuit for generating said predetermined bias current only during said predetermined time interval such that said zener diode provides said reference voltage only during said predetermined time interval.
